(19) United States
(12) Patent Application Publication
(10) Pub. No.: US 2026/0241506 A1
(43) Pub. Date: Aug. 20, 2026

(54) METHOD FOR SUCTIONING OFF PARTICLES, IN PARTICULAR WHEN CUTTING INDIVIDUAL PRINTED CIRCUIT BOARDS OUT OF A CIRCUIT BOARD PANEL, SUCTION DEVICE, SUCTION SYSTEM AND CUTTING MACHINE

(71) Applicant: SCHUNK Electronic Solutions GmbH, St. Georgen (DE)

(72) Inventors: Markus Ganter, Villingen (DE); Tobias Kühne, Rosenfeld (DE)

(21) Appl. No.: 18/876,643

(22) PCT Filed: Apr. 18, 2023
(86) PCT No.: PCT/EP2023/059961

§ 371 Date: Dec. 18, 2024

(30) Foreign Application Priority Data
Jun. 21, 2022 (DE) 102022115459.9

(51) Int. Cl. B23Q 11/00; H05K 3/00

(52) U.S. Cl. CPC B23Q 11/006; H05K 3/0052; H05K 3/0055

(57) ABSTRACT

A method for suctioning off particles when cutting workpieces out of a board material, and in particular when cutting individual printed circuit boards out of a circuit board panel, characterized in that for the cutting out the workpiece and when suctioning off of the particles arising when cutting out, a compressed air flow pulsating at a pulse frequency is directed at the workpiece in such a way that particles adhering to the workpiece are detached. The workpiece is set into vibration due to the impinging pulsating compressed air flow. A vibration frequency of the workpiece is measured during the suction process and the pulse frequency is regulated depending on the vibration frequency.

The invention relates to a method for suctioning off particles when cutting workpieces out of a board material, and in particular when cutting individual printed circuit boards out of a circuit board panel (circuit board panel). The invention further relates to a suction device, a suction system with such a suction device and a cutting machine for cutting workpieces out of board material with such a suction system and/or such a suction device.

When using industrial automation systems, the use of highly efficient and precise manufacturing technology is a basic requirement. An important method step in the production of electronic assemblies is the cutting of sheets of circuit board into individual assemblies, i.e., into individual printed circuit boards after being populated with components and then soldered. Given the complexity of today's assemblies and circuit structures, soiling and contamination of assemblies and printed circuit boards due to the resulting particles and dust are extremely critical. This not only reduces production yields in electronics manufacturing; undetected errors in assemblies can have far-reaching consequences for product safety. It is therefore particularly important to capture and separate particles and dust as completely as possible when processing sheets of circuit board and printed circuit boards.

It is known to suction off arising particles directly from the milling head or cutting head during processing using a suction system. However, very small particles can stick to the workpieces and are not captured and detached by the vacuum of the suction system. These deposits can, among other things, cause unwanted short circuits between the connections of the electronic components of the individual assemblies.

From an environmental perspective, minimal release of pollutants into the room air is also important. The resulting particles can harm the health of the operator of a sheet cutter or cutting machine if they are inhaled. Damage to the respiratory tract and the absorption of toxins into the body can be the result.

Investigations have also shown that the resulting milling particles are highly abrasive and lead to severe wear of components in the cutting machine. If the dust particles are not removed sufficiently, they can settle not only on the workpieces, but also in the entire cutting machine. This in turn leads to breakdowns and higher costs due to wear and maintenance of the cutting machine. Breakdowns and deviating tolerances are the result. Batches of processed workpieces can be poor in quality and cannot be further used for final products.

DE 101 52 401 A 1 discloses a milling machine with a chip extraction housing on the milling cutter.

DE102018211278A1 discloses a suction device for a processing apparatus, in particular a machining processing apparatus which has a compressed air channel that is configured to form a compressed air flow in the direction of the region to be cleaned.

The present invention is based on the object of increasing the process reliability when cutting workpieces, and in particular when cutting individual printed circuit boards out of a circuit board panel.

The object is achieved in particular by a method for suctioning off particles when cutting workpieces out of a board material, and in particular when cutting individual printed circuit boards out of a circuit board panel, in accordance with claim 1. In particular, it is therefore provided that when cutting out the workpiece and when suctioning off the particles arising when cutting out, a compressed air flow pulsating at a pulse frequency is directed at the workpiece in such a way that particles adhering to the workpiece are detached, and/or the workpiece is set into vibration due to the impinging pulsating compressed air flow.

This has the advantage that, on the one hand, particles can be detached directly from the printed circuit board by the pulsating compressed air flow and, on the other hand, the printed circuit board can be set into vibration by the pulsating compressed air flow, wherein adhering particles, in particular dust and/or chips, are detached from the workpiece. The vibration of the workpiece also reduces the settling of particles that have not yet been suctioned off onto the workpiece. As a result, suctioning off according to the method according to the invention ensures an end product that is at least largely and ideally completely particle and dust-free, thereby increasing process reliability.

In particular, very small particles are not captured by previously known suction systems from the prior art because the suction power, i.e., the possible generatable vacuum or volume flow, is insufficient and cannot be increased indefinitely. For particles with a particle size in the range of 40 to 80 μm, in particular smaller than 40 μm, as they arise when cutting individual assemblies from sheets of circuit board, adhesion to the workpiece predominates. The adhesion of these particles is caused in particular by electrostatic charging of the particles, whereby adhesion forces act between the particles and the printed circuit board and/or the components. These particles can only be removed from the electrical assemblies mechanically with conventional methods such as moving brushes. This poses the risk that the often small and sensitive components mounted and soldered on the printed circuit boards become damaged or torn off. The method according to the invention allows for the removal of the smallest particles from the surface of the printed circuit boards in the suction process with particles larger than 80 μm in a safe process, and the deposition of the particles due to the vibration of the printed circuit board is reduced. In addition, the particle load in the interior of the cutting machine is reduced, in particular in the processing region and on the cutting tool, which leads to a longer service life, longer cleaning and maintenance intervals and therefore reduces the costs of the manufacturing process.

It has been shown to be advantageous if the pulse frequency lies in the range of 1-60 Hz, in particular 20-40 Hz, and further in particular 30 Hz. By means of these frequencies, particles can be removed from the tool and printed circuit board, and the circuit board can be optimally stimulated to vibrate by the compressed air flow without the components located thereon being damaged or detached by the vibrations.

It is conceivable for the pulse frequency to be predetermined or settable and for the pulse frequency to be adjustable depending on workpiece parameters. To simplify the method, the pulse frequency can be predetermined and controlled within a certain range. For other applications, for example when different printed circuit boards are cut one after the other, the pulse frequency can be adjustable. Advantageously and to further increase process reliability, the pulse frequency can be adjusted depending on workpiece parameters. This can be done manually, for example, or using a database in which workpiece parameters are saved.

Furthermore, it is advantageous if a vibration frequency of the workpiece is measured during the suction process and if the pulse frequency is regulated depending on the vibration frequency. This is an advantageous development of the previous aspect, because by controlling the pulse frequency of the compressed air flow, the vibration frequency of the workpiece can always remain in a safe range for the detachment of the particles. This can further increase process reliability.

It is also conceivable that the vibration frequency of the workpiece is measured by means of an optical camera or a vibration sensor. A camera is often already present in a cutting machine to detect the circuit board panel to be cut. The generated images can also be used to determine the vibration frequency. If the vibration amplitude of the vibrating circuit board panel is too small and cannot be detected by the camera, it is advantageous to provide a vibration sensor for reliable measurement of the vibration quantities.

It is also advantageous if the compressed air forming the compressed air flow is ionized. Electrostatic potentials are built up by the friction of the cutting tool, in particular the milling cutter or a saw, during the cutting process. Due to the electrostatic potential, the particles adhere more strongly to the circuit board panel. To avoid this, the electrostatic potential of the particles must be reduced. With ionized molecules in the compressed air, electrostatic potentials, in particular of the particles, can be reduced or balanced, and the particles are more easily released from the circuit board panel, the printed circuit boards and the components of the cutting head.

It can further be provided that the compressed air flow is generated by at least one and preferably three compressed air nozzles within a suction opening extending around a central axis and forms a vortex around the central axis. The formation of a vortex further increases the detachment effect of the particles.

It has also been shown to be advantageous if the suctioned off air volume flow including particles is greater than the blown-in compressed air flow. This can ensure that a vacuum which leads to the particles being suctioned off can be applied in a safe process.

The object mentioned at the outset is also achieved by a suction device for suctioning off particles when cutting workpieces out of a board material, and in particular when cutting individual printed circuit boards out of a circuit board panel, and further in particular for carrying out the method according to the invention. The suction device provides a suction opening extending around a central axis and at least one compressed air nozzle provided for generating a compressed air flow directed along a main air flow direction. The compressed air nozzle is arranged in particular within the suction opening in such a way that the main air flow direction is directed towards the workpiece to be cut. Furthermore, a compressed air line is provided to supply the compressed air nozzle with compressed air. A valve unit is provided within the compressed air line, which is configured to generate a compressed air flow pulsating at a pulse frequency in such a way that particles adhering to the workpiece are detached, and/or the workpiece is set into vibration due to the impinging pulsating compressed air flow. This can further increase process reliability.

It can further be provided that the valve unit is designed as an electrically controlled switching valve, and a control unit is provided for actuating the switching valve to generate the pulse frequency. This has the advantage that a simple actuation of the switching valve and integration of the method according to the invention into a commercially available control system or into a machine control system is possible.

It has also proven advantageous if the switching valve is actuated by the control unit in such a way that the pulse frequency lies in the range of 1-60 Hz, in particular of 20-40 Hz, and further in particular of 30 Hz. Advantageously, the pulse frequency of the compressed air flow is transferred to the workpiece, and the workpiece then vibrates to detach adhering particles.

It is further conceivable for the control unit to be configured to control the switching valve depending on workpiece parameters and/or to regulate it depending on a measured vibration frequency. This is advantageous because it ensures even greater process reliability by maintaining tolerances in the vibration frequency.

It can further be provided that an ionizer is provided for ionizing the compressed air forming the compressed air flow. This allows the ionized compressed air to be generated in the proximity of the cutting machine to ensure the best possible ionization of the air molecules that are used to form the compressed air. It is therefore advantageous if the at least one compressed air nozzle is made of a non-conductive material, in particular of a non-conductive plastics material. The non-conductive plastics material advantageously maintains the ionized state of the air molecules, and the ionization of the air molecules is not compensated until the compressed air of the compressed air flow hits the workpiece or the particles to be removed.

Furthermore, it can be provided that a nozzle ring forming the suction opening is provided, on which the at least one compressed air nozzle and preferably three compressed air nozzles are arranged at an angular distance of 120° from one another. With three compressed air nozzles, an advantageous mass of compressed air can be directed onto the workpiece through the compressed air flow. The arrangement of the compressed air nozzles on a component makes mounting on a cutting machine convenient.

It is advantageous if the main air flow direction of the at least one compressed air nozzle runs in such a way that, during operation, the compressed air flow generates a vortex around the central axis.

It can further be provided that the nozzle ring has a round outer contour with a flat spot, wherein one or more compressed air connections are provided at the flat spot.

It is also advantageous if the nozzle ring has, on an upper side facing the suction opening, a circumferential shoulder surrounding the suction opening with a shoulder edge and if the at least one compressed air nozzle is provided on the shoulder edge. This has the advantage that the arrangement of the compressed air nozzle on the shoulder edge causes little disturbance to the compressed air flow emerging the compressed air nozzle and that this can develop in the best possible way.

The nozzle ring can have an upper side facing the suction opening and a lower side facing away from the suction opening, wherein the upper side and lower side are parallel to each other.

It is further conceivable that the nozzle ring has a sensor holder for a tool sensor, wherein a sensor nozzle directed towards the sensor holder is provided. The sensor is in particular configured to detect wear or breakage of the cutting tool. Due to deposits of particles, the function of the sensor can be limited since this can in particular be an optical sensor. The sensor nozzle is advantageously configured to blow off the deposited particles on the sensor with compressed air.

The object mentioned at the outset is also achieved by a suction system with a vacuum source, with vacuum lines for connecting a suction device to the vacuum source and with adjustment devices for adjusting the vacuum lines to a movable position of the suction device, wherein the suction device is a suction device according to the invention and/or is operated according to the method according to the invention. Advantageously, the suction device and the method according to the invention are adapted to one another in such a way that the suction functions optimally and all components interact with one another. This leads to an increase in process reliability.

The object mentioned at the outset is also achieved by a cutting machine for cutting workpieces out of a board material, in particular individual printed circuit boards from a circuit board panel, with a cutting head, with a central control unit, and with a suction system with a suction device according to the invention. This suction device is operated in particular according to a method according to the invention, wherein the control unit is further configured in particular to actuate the cutting head and the valve unit of the suction device in parallel.

Further details and advantageous designs of the invention can be found in the following description, on the basis of which embodiments of the invention are described and explained in more detail.

In the drawings:

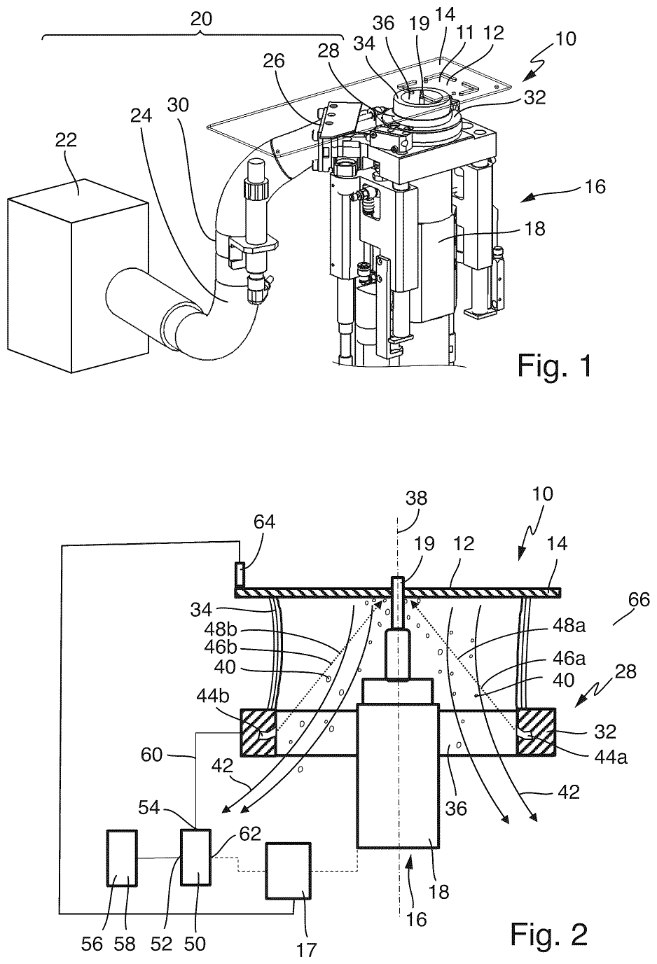

FIG. 1: is a cutting machine for cutting printed circuit boards out of a circuit board panel with a suction system with a suction device;

FIG. 2: is a schematic sectional view of the suction device in accordance with FIG. 1;

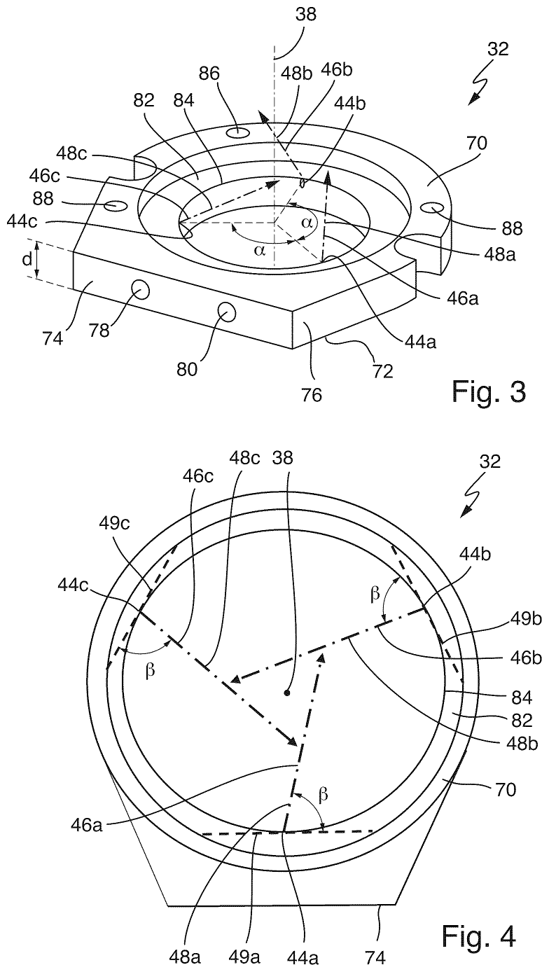

FIG. 3: is a nozzle ring of the suction device in accordance with FIG. 1;

FIG. 4: is a plan view of the nozzle ring in accordance with FIG. 3;

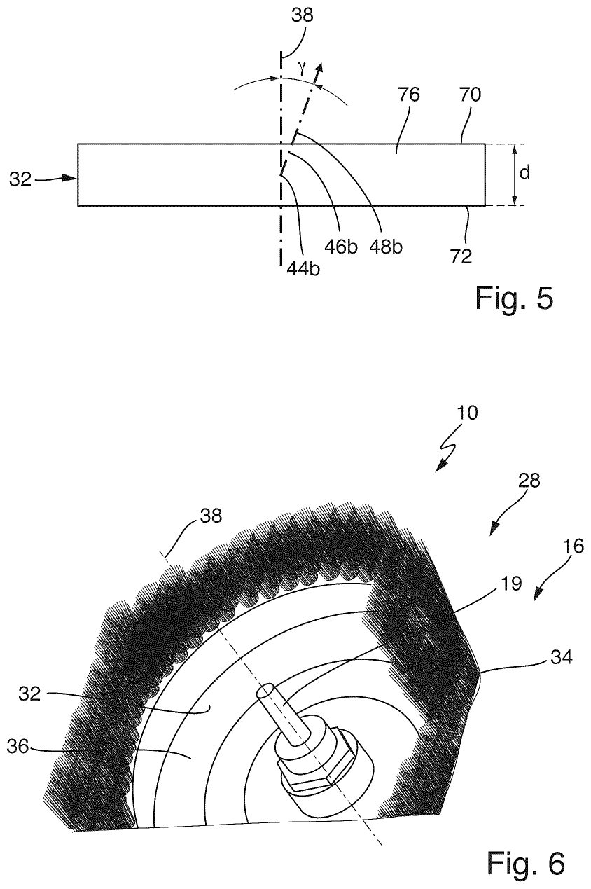

FIG. 5: is a side view of the nozzle ring in accordance with FIG. 4; and

FIG. 6: is a view of the cutting machine in accordance with FIG. 1 obliquely from above into the suction opening.

In FIG. 1, a cutting machine 10 is shown for cutting a workpiece 11 out of a board material, namely for cutting printed circuit boards 12 out of a plate-shaped printed circuit board panel 14.

The cutting machine 10 comprises a cutting head 16, a central control unit 17 (shown in FIG. 2) and a suction system 20. Axle drives for moving the cutting head 16, as well as other components of the cutting machine 10 are not shown for the sake of clarity.

The cutting head 16 has a drive 18 and a cutting tool 19, such as a milling cutter, for cutting the printed circuit board 12 out of the printed circuit board panel 14.

The suction system 20 comprises a vacuum source 22 and vacuum lines 24 with a connection 26 to a suction device 28 which is arranged on the cutting head 16. Furthermore, an adjustment device 30 is shown for adapting the vacuum lines 24 to the position of the suction device 28 in order to be able to follow variable position of the movable cutting head 16. Preferably, a plurality of adjustment devices (not shown) are provided to adapt the vacuum lines 24 in all directions of movement of the cutting head 16.

The suction device 28, which is also shown in FIG. 2, comprises an annular nozzle ring 32 and a brush ring 34 arranged on the nozzle ring 32. The nozzle ring 32 forms a suction opening 36 around a central axis 38. FIG. 6 shows a view obliquely from above into the suction opening 36. The brush ring 34 or its bristles lie—as can be seen in FIG. 6—on the circuit board panel 14 and/or on the printed circuit board 12 when the circuit board 12 is cut out.

In FIG. 2, the suction device 28 with the nozzle ring 32 is shown schematically simplified as a sectional view around the cutting head 16. The drive 18 of the cutting head 16, which is designed, for example, as an electric motor or pneumatic motor, drives the cutting tool 19. The cutting tool 19 processes the circuit board panel 14 and cuts out individual printed circuit boards 26. When cutting out, particles 40 such as dust and/or chips arise. Furthermore, FIG. 2 shows that the particles 40 arising during processing of the circuit board panel 14 are suctioned off into a suctioned off air volume, indicated by the arrows 42, through the suction opening 36 due to the vacuum generated by the vacuum source 22.

The nozzle ring 32 has a total of three compressed air nozzles 44a, 44b and 44c, as they are shown in FIG. 3, wherein only two compressed air nozzles 44a and 44b are shown in FIG. 2 due to the sectional view. The compressed air nozzles 44a, 44b and 44c each form a compressed air flow 46a, 46b and 46c along a main air flow direction 48a, 48b and 46c towards the printed circuit board 12 and/or the circuit board panel 14.

Furthermore, an electrical switching valve 50 is shown schematically in FIG. 2, which has two compressed air connections 52 and 54. The compressed air connection 52 is connected to a compressed air source 56 and an air ionizer 58. The compressed air connection 54 is connected to a compressed air line 60 which connects the switching valve 50 to the compressed air nozzles 44a, 44b and 44c in the nozzle ring 32.

The switching valve 50 is designed as an electrical quick-switching valve and has an interface 62. The switching valve 50 is connected to the central control unit 17 of the cutting machine 10 via the interface 62. The control unit 17 controls the switching valve 50 so that the switching valve 50 influences the compressed air, which comes from the compressed air source 56 and is advantageously ionized, and ultimately forms the compressed air flows 46a, 46b and 46c, in such a way that the compressed air flows 46a, 46b and 46c emerging from the compressed air nozzles 44a, 44b and 44c pulsate. The switching valve 50 is actuated by the control unit 17 in particular in such a way that the pulse frequency lies in the range of 1-60 Hz. The pulse frequency can advantageously be variably adjusted to the workpiece parameters of the circuit board panel 14.

Due to the pulsating compressed air flows 46a, 46b and 46c, the printed circuit board panel 14 advantageously vibrates and particles 40 deposited thereon, such as chips and/or dust, are removed or shaken off so that the detached particles 40 can be suctioned off.

A sensor 64 shown in FIG. 2 for recording the vibration frequency of the circuit board panel 14 is coupled to the circuit board panel 14 and connected to the control unit 17. By using the vibration frequency of the printed circuit board panel 14 as a measured variable, regulation of the vibration frequency of the printed circuit board 12 by means of the control unit 17 is possible. Furthermore, the control unit 17 is also connected in particular to the drive 18 of the cutting head 16 and controls this in parallel with the switching valve 50 during the cutting process as well as other machine functions of the cutting machine 10.

During the cutting process, the brush ring 34 lies against the circuit board panel 14 and/or the printed circuit board 12 to be cut out and seals the suction opening 36 from the environment 66 so that the vacuum extends to the circuit board panel 14. This makes it particularly easy to capture and suction off particles 40. It is advantageous if the air volume flow suctioned off by the vacuum source 22, which is indicated by the arrows 42 in FIG. 2, is at least as large as the volume of the generated and detached particles 40 together with the volume of the blown-in compressed air flows 46a, 46b and 46c.

FIGS. 3, 4 and 5 show an embodiment of the nozzle ring 32 from FIGS. 1 and 2. The nozzle ring 32 has an annular base body which forms the suction opening 36 around the central axis 38. An upper side 70, and parallel thereto below at a distance d, a lower side 72 faces the suction opening 36. Furthermore, the nozzle ring 32 has a flat spot 74 on the outer contour 76 at which the two compressed air connections 78 and 80 are located. Furthermore, the nozzle ring 32 has the three compressed air nozzles 44a, 44b and 44c which are connected to the compressed air connection 78. The compressed air connection 78 is connected to the switching valve 50 during operation.

On the upper side 70, the nozzle ring 32 further has a circumferential shoulder 82 with a shoulder edge 84 surrounding the suction opening 36. The three compressed air nozzles 44a, 44b and 44c are arranged on the shoulder edge 84 at an angular distance a of 120° from each other.

The compressed air nozzles 44a, 44b and 44c are designed in such a way that they guide the compressed air flows 46a, 46b and 46c emerging from them along a relevant main air flow direction 48a, 48b or 48c, which are each indicated as arrows. The compressed air flows 46a, 46b and 46c are directed onto the circuit board panel 14 and/or printed circuit board 12 in such a way that a vortex is formed around the central axis 38. The main air flow directions 48a, 48b and 48c do not run parallel to the central axis 38, but obliquely. As can be seen in FIG. 4, the main air flow directions 48a, 48b and 48c in plan view with a relevant tangent 49a, 49b and 49c touching the shoulder edge 84 preferably enclose an angle β in the range of 45° to 90°. The relevant tangent 49a, 49b and 49c lies at the center of the compressed air nozzle 44a, 44b and 44c belonging to the main air flow directions 48a, 48b or 48c on the shoulder edge 84. In the vertical direction, as shown in FIG. 5, the main air flow directions 48a, 48b and 48c in a side view of the relevant compressed air nozzle 44a, 44b and 44c form an angle with the central axis 38 γ in the range of 0° to 30°. For the sake of clarity, only the compressed air nozzle 44b, the compressed air flow 46b and the main air flow direction 48b are shown in FIG. 5. By combining the arrangement of the compressed air nozzle 44a, 44b and 44c at the angle α and the formation of the main air flow directions 48a, 48b and 48c in the direction of the two angles β and γ, during operation of the suction device 28, a vortex is formed around the central axis 38 by the compressed air flows 46a, 46b and 46c.

Furthermore, the nozzle ring 32 has a positioning bore 86 which is provided so that the correct mounting position can be easily achieved when arranging the nozzle ring 22 on a cutting head 16 during replacement and/or maintenance. The positioning bore 86 ensures that the compressed air nozzles 44a, 44b and 44c point in the direction of the cutting tool 19 during operation.

Furthermore, bores 88 are provided for mounting the brush ring 34 on the nozzle ring 32. A thread can be provided in the bores 88 for this purpose.

In addition, a sensor nozzle (not shown) is provided which is connected to the compressed air connection 80, as well as a sensor holder (not shown) for a tool sensor (not shown); this tool sensor can be optical, for example. Using the optical tool sensor which is connected to the control unit 17, damage, breakage or wear of the cutting tool 19 can be detected during operation of the cutting machine 10. The status of the cutting tool 19 can be signaled to an operator, or further automated processes to ensure process reliability can be carried out by the control unit 17. The sensor nozzle is provided to blow off any deposited particles 40 from the tool sensor using compressed air in order to ensure proper functioning of the sensor. The compressed air can also pulsate and be supplied by the switching valve 50 via the compressed air line 60.

The nozzle ring 32 is preferably made of a non-electrically conductive plastics material and is preferably manufactured additively. The compressed air that is ionized by the ionizer 58 still remains ionized if the nozzle ring 32 is made of a non-conductive plastics material. As a result, the compressed air can further improve the detachment of particles 40 adhering to the printed circuit board panel 14 and/or printed circuit board 12 or other machine components due to electrostatics.

FIG. 6 shows a view of the cutting machine 10 into the suction opening 36 of the suction device 28. The cutting tool 19 of the cutting head 16 lies on the central axis 38 of the suction opening 36, wherein the suction opening 36 is surrounded by the nozzle ring 32. The brush ring 34 is arranged on the nozzle ring 32. The brush ring 34 is designed to be adjustable in height.

Suctioning off of the particles 40 in the cutting machine 10 takes place in particular as follows:
Air is compressed into compressed air by the compressed air source 56, ionized by the ionizer 58 and fed to the compressed air line 60.
The electric switching valve 50 is actuated by the control unit 17 in such a way that the outflowing compressed air pulsates with a pulse frequency of in particular 1-60 Hz.
The compressed air nozzles 44a, 44b and 44c in the nozzle ring 32 each form a pulsating compressed air flow 46a, 46b and 46c from the pulsating compressed air.
The pulsating compressed air flows 46a, 46b and 46c are directed along a relevant main air flow direction 48a, 48b and 48c onto the circuit board panel 14 and/or the printed circuit board 12. By suitable selection of the relevant main air flow direction 48a, 48b and 48c, a vortex is formed around the central axis 38 of the suction opening 36.
Due to the pulsation of the compressed air flows 46a, 46b and 46c impinging on the circuit board panel 14 and/or the printed circuit board 12, particles 40 are detached from the circuit board panel 14 and/or the circuit board 12. The detachment of the particles 40 is advantageously supported by the formed vortex.
The pulse frequency of the pulsating compressed air flows 46a, 46b and 46c impinging on the circuit board panel 14 and/or the printed circuit board 12 can be transferred to the circuit board panel 14 and/or the printed circuit board 12 and cause the circuit board panel 14 and/or the printed circuit board 12 to vibrate. As a result, adhering particles 40 are detached, as they were shaken off, by electrostatic forces. The ionized state of the compressed air further ensures a reduction of the electrostatic forces and promotes the detachment of the very small adhering particles 40.
By an applied vacuum 42, the detached particles 40 as well as the volume of the blown-in compressed air flows 46a, 46b and 46c are suctioned off.

1-18. (canceled)

19. A method for suctioning off particles when cutting workpieces out of a board material, and in particular when cutting individual printed circuit boards out of a circuit board panel, characterized in that for the cutting out the workpiece and when suctioning off of the particles arising when cutting out, a compressed air flow pulsating at a pulse frequency is directed at the workpiece in such a way that the particles adhering to the workpiece are detached, and that the workpiece is set into vibration due to an impinging pulsating compressed air flow, wherein a vibration frequency of the workpiece is measured during a suction process, and wherein the pulse frequency is regulated depending on the vibration frequency.

20. The method according to claim 19, characterized in that the pulse frequency lies in the range of 1-60 Hz.

21. The method according to claim 19, wherein the pulse frequency is predetermined or settable, and wherein the pulse frequency is adjustable depending on workpiece parameters.

22. A method according to claim 19, characterized in that the vibration frequency of the workpiece is measured by an optical camera or a vibration sensor.

23. The method according to claim 19, characterized in that the compressed air forming the compressed air flow is ionized.

24. The method according to claim 19, characterized in that the compressed air flow is generated by at least one nozzle within a suction opening extending around a central axis and forms a vortex around the central axis.

25. The method according to claim 19, characterized in that the suctioned off air volume flow including particles is greater than the blown-in compressed air volume flow.

26. A suction device for suctioning off particles when cutting workpieces out of a board material, and in particular when cutting individual printed circuit boards out of a circuit board panel, and further for carrying out a method according to claim 19, with a suction opening extending around a central axis, with at least one compressed air nozzle provided for generating a compressed air flow directed along a main air flow direction,
wherein the compressed air nozzle is arranged within the suction opening in such a way that the main air flow direction is directed towards the workpiece to be cut,
wherein a compressed air line for supplying the compressed air nozzle with compressed air is provided, and
wherein a valve unit is provided within the compressed air line, which is configured to generate a compressed air flow pulsating at a pulse frequency in such a way wherein particles adhering to the workpiece are detached and wherein the workpiece is set into vibration due to the impinging pulsating compressed air flow,
wherein the valve unit is designed as an electrically controlled switching valve, and a control unit is provided for actuating the switching valve to generate the pulse frequency, and
wherein the control unit is configured to control the switching valve depending on a measured vibration frequency of the workpiece.

27. The suction device according to claim 26, characterized in that the switching valve is actuated by the control unit in such a way that the pulse frequency lies in the range of 1-60 Hz, in particular of 20-40 Hz, and further in particular of 30 Hz.

28. The suction device according to claim 26, characterized in that the control unit is configured to control the switching valve depending on workpiece parameters.

29. The suction device according to claim 26, characterized in that an ionizer is provided for ionizing the compressed air forming the compressed air flow.

30. The suction device according to claim 26, characterized in that a nozzle ring forming the suction opening is provided, on which the at least one compressed air nozzle and preferably three compressed air nozzles are arranged at a distance of 120° from one another.

31. The suction device according to claim 26, characterized in that the nozzle ring has, on an upper side facing the suction opening, a circumferential shoulder surrounding the suction opening with a shoulder edge, and in that the at least one compressed air nozzle is provided on the shoulder edge.

32. The suction device according to claim 26, characterized in that the nozzle ring has a sensor holder for a tool sensor, wherein a sensor nozzle directed towards the sensor holder is provided.

33. A suction system with a vacuum source, with vacuum lines for connecting a suction device to the vacuum source, with adjustment devices for adjusting the vacuum lines to a movable position of the suction device, wherein the suction device is the suction device according to claim 26.

34. A cutting machine for cutting workpieces out of board material, in particular individual printed circuit boards from a circuit board panels, with a cutting head, with a central control unit, and with a suction system according to claim 33, wherein the control unit is configured to control the cutting head and the valve unit of the suction device in parallel.
